(19) United States
(12) Patent Application Publication
(10) Pub. No.: US 2007/0128757 A1
(43) Pub. Date: Jun. 7, 2007

(54) Method for forming comb electrodes using self-alignment etching

(75) Inventors: Young-chul Ko, Yongin-si (KR); Hyun-ku Jeong, Chungju-si (KR); Seok-whan Chung, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/588,298

(22) Filed: Oct. 27, 2006

(30) Foreign Application Priority Data
Dec. 1, 2005 (KR) 10-2005-0116637

(51) Int. Cl. H01L 21/00

(52) U.S. Cl. 438/50

(57) ABSTRACT

A method of forming comb electrodes using self alignment etching is provided. A method of forming a stationary comb electrode and a movable comb electrode in first and second silicon layers of a SOI (Silicon-on-Insulator) substrate, respectively, using etching. The method involves sequentially etching the first silicon layer, the insulating layer, and the second silicon layer using an alignment mark formed in the first silicon layer. According to the method, the stationary comb electrode and the movable comb electrode are self-aligned for etching by patterning the first silicon layer.

### CROSS-REFERENCE TO RELATED PATENT APPLICATION

This application claims the benefit of Korean Patent Application No. 10-2005-0116637, filed on Dec. 1, 2005, in the Korean Intellectual Property Office, the disclosure of which is incorporated herein in its entirety by reference.

### BACKGROUND OF THE INVENTION

1. Field of the Invention

The present invention relates to a method for etching upper and lower structures in a Micro Electro-Mechanical Systems (MEMS) structure arranged in a staggered fashion using a self-alignment technique.

2. Description of the Related Art

When manufacturing a MEMS structure such as an optical scanner for a flat panel display, double-sided etching may be required. Respective alignment marks are required for etching first and second surfaces. However, formation of alignment marks on the two surfaces may cause a large alignment error. This alignment error results in misalignment between comb electrodes in a MEMS structure, thus causing a failure in the MEMS device.

Therefore, to reduce an alignment error in double-sided etching, there is a need for a technique for etching upper and lower structures using alignment marks formed on only one surface.

### SUMMARY OF THE INVENTION

The present invention provides a method for forming comb electrodes using self alignment etching that can reduce a misalignment error in upper and lower structures in a Micro Electro-Mechanical Systems (MEMS) structure requiring double-sided etching.

According to an aspect of the present invention, there is provided a method of forming a stationary comb electrode and a movable comb electrode in first and second silicon layers of a SOI (Silicon-on-Insulator) substrate, respectively, using etching including the steps of: forming a first mask on a portion of the first silicon layer where the stationary comb electrode forming a second mask on the first mask and a portion of the first silicon layer corresponding to a portion of the second silicon layer where the movable comb electrode will be formed, and forming an anti-oxidation layer on a portion of the second silicon layer corresponding to the portion of the first silicon layer where the stationary comb electrode will be formed; etching the first silicon layer exposed through the second mask to a predetermined depth; removing the second mask and etching the first silicon layer exposed through the first mask so that a first portion of the first silicon layer corresponding to the portion of the second silicon layer for forming the movable comb electrode remains; etching the insulating layer of the SOI substrate exposed through the first mask and the first portion; etching the second silicon layer exposed through the first mask and the first portion; removing the first mask and forming a silicon oxide layer on an exposed silicon layers; removing the anti-oxidation layer and etching a portion of the second silicon layer not covered by the silicon oxide layer; and removing the silicon oxide layer.

The anti-oxidation layer is separated from the portion of the second silicon layer where the movable comb electrode will be formed. The anti-oxidation layer may be wider than the portion of the first silicon layer where the stationary comb electrode will be formed.

The anti-oxidation layer may be made of silicon nitride using an alignment mark formed in the first silicon layer.

Alternatively, the method may include the steps of: forming first and second anti-oxidation layers on a portion of the first silicon layer corresponding to a portion of the second silicon layer where the movable comb electrode and a portion of the second silicon layer corresponding to a portion of the first silicon layer where the stationary comb electrode will be formed, respectively, and forming a mask on the first anti-oxidation layer and the portion of the first silicon layer where the stationary comb electrode will be formed; sequentially etching the first silicon layer, an insulating layer and the second silicon layer exposed through the mask; removing the mask and forming a silicon oxide layer on an exposed silicon layers; removing the first and second anti-oxidation layers and etching portions of the silicon layers not covered by the silicon oxide layer; and removing the silicon oxide layer.

### BRIEF DESCRIPTION OF THE DRAWINGS

The above and other aspects of the present invention will become more apparent by describing in detail exemplary embodiments thereof with reference to the attached drawings in which:

FIG. 1 is a perspective view of a related art optical scanner disclosed in U.S. Patent Publication No. 2006/0082250;

FIG. 2 is a schematic cross-sectional view of comb electrodes as shown in FIG. 1;

FIGS. 3A-3C are cross-sectional views illustrating steps in a method of manufacturing a structure as shown in FIG. 2;

FIGS. 4A-4H are cross-sectional views illustrating steps in a method of forming comb electrodes using self alignment etching according to an exemplary embodiment of the present invention; and

FIGS. 5A-5G are cross-sectional views illustrating steps in a method of forming comb electrodes using self alignment etching according to another exemplary embodiment of the present invention.

### DETAILED DESCRIPTION OF EXEMPLARY EMBODIMENTS OF THE INVENTION

Methods of forming comb electrodes using self alignment etching according to exemplary embodiments of the present will now be described with reference to the attached drawings. In the drawings, some elements may be exaggerated for clarity or omitted to avoid complexity and to aid in the understanding of the present invention. This is not intended to limit the technical scope of the present invention.

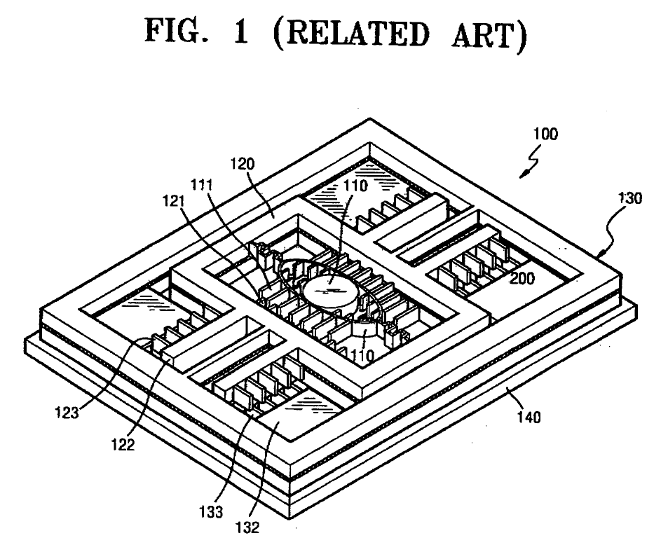

FIG. 1 is a perspective view of an optical scanner 100 disclosed in U.S. Patent Publication No. 2006/0082250.

Referring to FIG. 1, the optical scanner 100 is actuated in two axis directions by first movable comb electrodes 111 and first stationary comb electrodes 121 disposed between a stage 110 and a movable frame 120 and second movable comb electrodes 123 and second stationary comb electrodes 133 disposed between a first member 122 extending from the movable frame 120 and a second member 132 extending from a stationary frame 130. The first and second stationary comb electrodes 121 and 133 are perpendicular to a base substrate 140. The first and second movable comb electrodes 111 and 123 are separated from the base substrate 140 corresponding to the first and second stationary comb electrodes 121 and 133 for rotation.

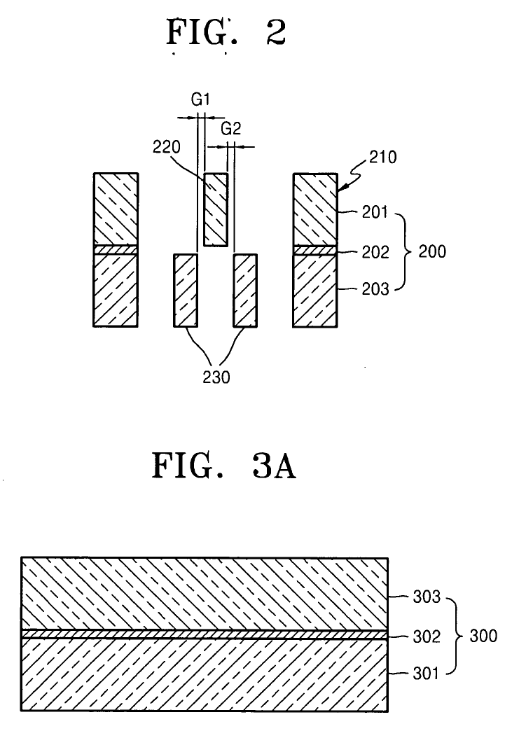

FIG. 2 is a schematic cross-sectional view of comb electrodes as shown in FIG. 1. Referring to FIG. 2, a frame 210 is formed by etching a silicon-on-insulator (SOI) substrate 200 including a first silicon layer 201, an insulating layer 202, and a second silicon layer 203. The frame 210 may correspond to the movable frame 120 and the stationary frame 130 shown in FIG. 1. A movable comb electrode 220 formed from the first silicon layer 201 is arranged in a staggered fashion relative to a stationary comb electrode 230 formed from the second silicon layer 203. The distances G1 and G2 between the movable comb electrode 220 and the stationary comb electrode 230 may be designed to be equal. When the distances G1 and G2 are not sufficiently equal, the stage 110 may not rotate normally. In order to make the distances G1 and G2 uniform, it is necessary to reduce an error during etching of the comb electrodes 220 and 230 in the first and second silicon layers 201 and 203 using an alignment mark.

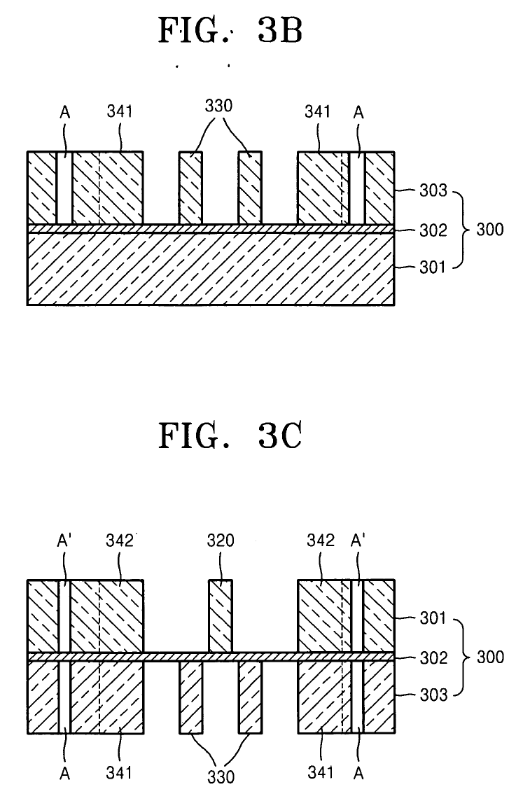

FIGS. 3A-3C are cross-sectional views illustrating steps in a method of manufacturing a structure as shown in FIG. 2.

Referring to FIG. 3A, a SOI substrate 300 in which a first silicon layer 301, an insulating layer 302, and a second silicon layer 303 have been sequentially formed is prepared. Referring to FIG. 3B, the second silicon layer 303 is patterned to form stationary comb electrodes 330, a portion 341 of a frame, and an alignment mark A. The alignment mark A is formed by etching a portion of the second silicon layer 303 and the portion of the second silicon layer 303 containing the alignment mark A is removed from a complete structure.

Referring to FIG. 3C, with the first silicon layer 301 of the SOI substrate 300 facing upwardly, the first silicon layer 301 is patterned using the alignment mark A to form a movable comb electrode 320 and the remaining portion 342 of the frame. In this case, an alignment mark A may be formed in the first silicon layer 301 and used to pattern the movable comb electrode 320 and the remaining portion 342 of the frame.

Subsequently, an exposed portion of the insulating layer 302 is selectively etched and the portions of the first and second silicon layers 301 and 302 containing the alignment marks A' and A are scribed to form a structure as shown in FIG. 2.

According to the manufacturing process illustrated in FIGS. 3A-3C, an alignment error may significantly increase when the first silicon layer 301 is patterned using a microscope while observing the alignment mark A formed in the second silicon layer 303 with another microscope.

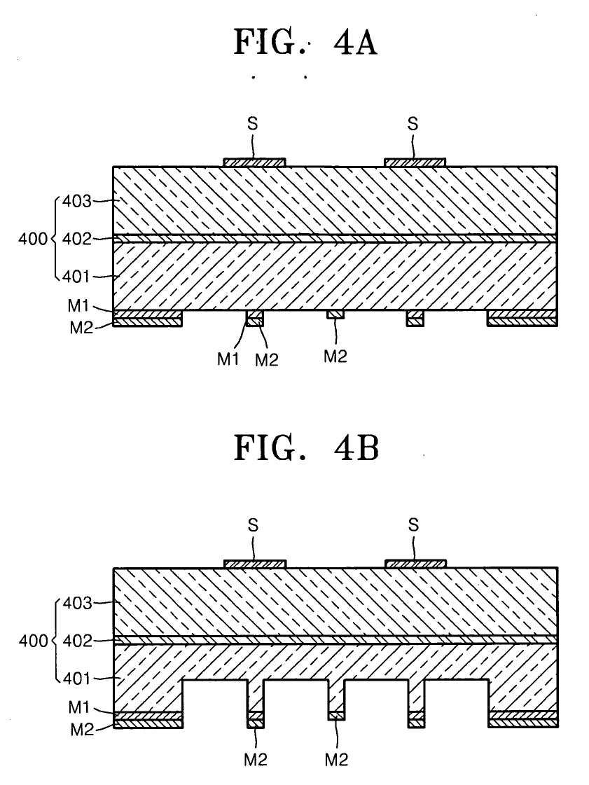

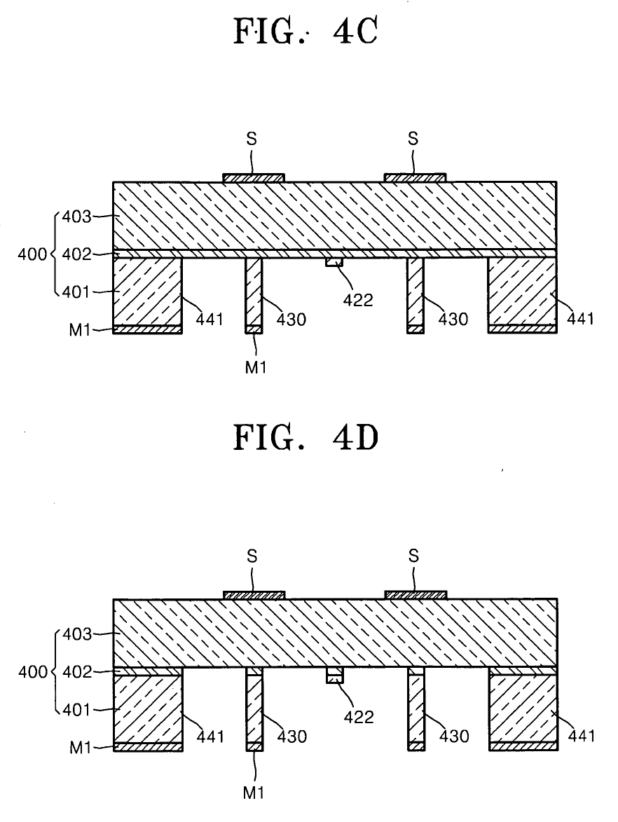

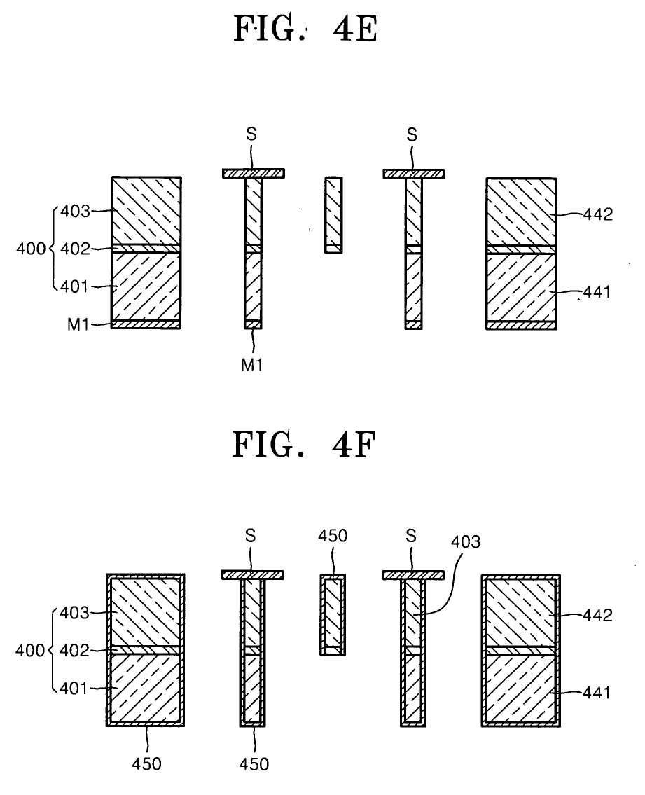

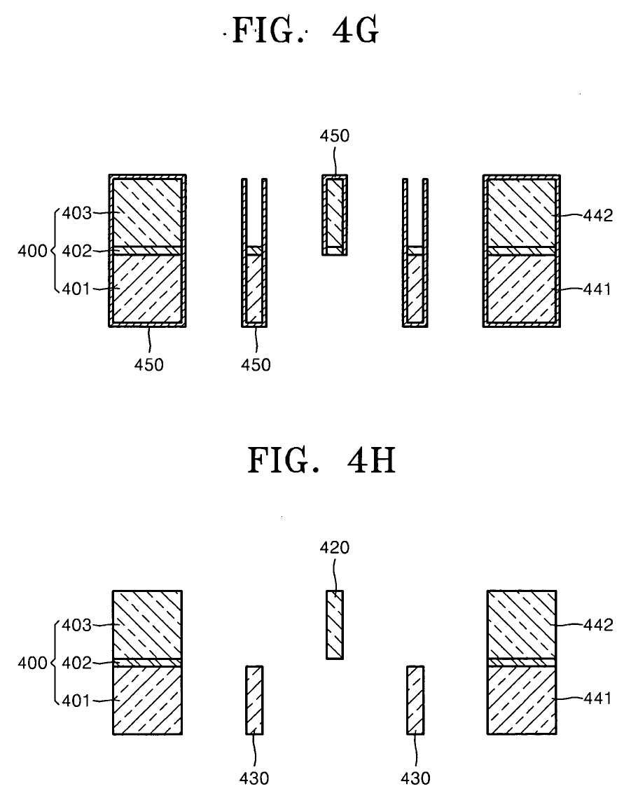

FIGS. 4A-4H are cross-sectional views illustrating steps in a method of forming comb electrodes using self alignment according to an exemplary embodiment of the present invention.

Referring to FIG. 4A, a SOI substrate 400 in which a first silicon layer 401, an insulating layer 402 and a second silicon layer 403 have been sequentially formed is prepared. The first and second silicon layers 401 and 403 of the exemplary embodiment may have thicknesses of 500 μm. The insulating layer 402 may be a 2 μm thick silicon oxide layer.

Then, a first mask M1 is formed on the first silicon layer 401 and a second mask M2 is formed on the first mask M1. The first mask M1 is formed on portions of first silicon layer 401 in which a stationary comb electrode and a frame will be formed. The second mask M2 is formed in portions of the first silicon layer 401 corresponding to portions of the second silicon layer 403 in which movable comb electrodes will be formed and on the first mask M1. The first and second masks M1 and M2 have different etch rates with respect to silicon as well as specific etch solution.

Subsequently, an anti-oxidation layer S is formed at a position on the second silicon layer 403 corresponding to the portion of the first silicon layer 401 in which the stationary comb electrode will be formed. The anti-oxidation layer S may be formed of silicon nitride. The anti-oxidation layer S may be formed using an alignment mark (not shown) formed in the first silicon layer 401 and may be wider than the portion of the first silicon layer 401 for forming the stationary comb electrode. The anti-oxidation layer S should be separated from the portion of the second silicon layer 403 for forming the movable comb electrode.

Referring to FIG. 4B, a portion of the first silicon layer 401 exposed through the second mask M2 is etched to a predetermined depth, followed by removal of the second mask M2 as illustrated in FIG. 4C. Subsequently, a portion of the first silicon layer 401 exposed through the first mask M1 is etched to expose the insulating layer 402 and to form stationary comb electrodes 430 and a portion 441 of a frame. In this case, a portion 422 of the first silicon layer 401 corresponding to the portion of the second silicon layer 403 for forming a movable comb electrode remains on the insulating layer 402 after etching. The first and second masks M1 and M2 have been used to form this portion 422. This portion 422 is needed to protect the insulating layer 402 corresponding to the portion of the second silicon layer 403 for forming the movable comb electrode against etching.

Referring to FIG. 4D, a portion of the insulating layer 402 exposed through the first mask M1 and the portion 422 is etched. Referring to FIG. 4E, a portion of the second silicon layer 403 exposed through the first mask M1 and the portion 422 are etched. Referring to FIG. 4F, the first mask M1 is removed. Subsequently, the exposed silicon layers are oxidized to form a silicon oxide layer 450 on the exposed structure.

Referring to FIG. 4G, the anti-oxidation layer S is removed, followed by removal of the underlying portion of the second silicon layer 403. Referring to FIG. 4H, the exposed silicon oxide layer 450 is removed to form movable and stationary comb electrodes 420 and 430 and the remaining portion 442 of the frame.

According to the method of the exemplary embodiment for etching a Micro Electro-Mechanical Systems (MEMS) structure illustrated in FIGS. 4A-4H, the stationary and movable comb electrodes 420 and 430 are self-aligned for etching by patterning the first silicon layer using the alignment mark formed in the first silicon layer, thereby eliminating an alignment error between upper and lower structures.

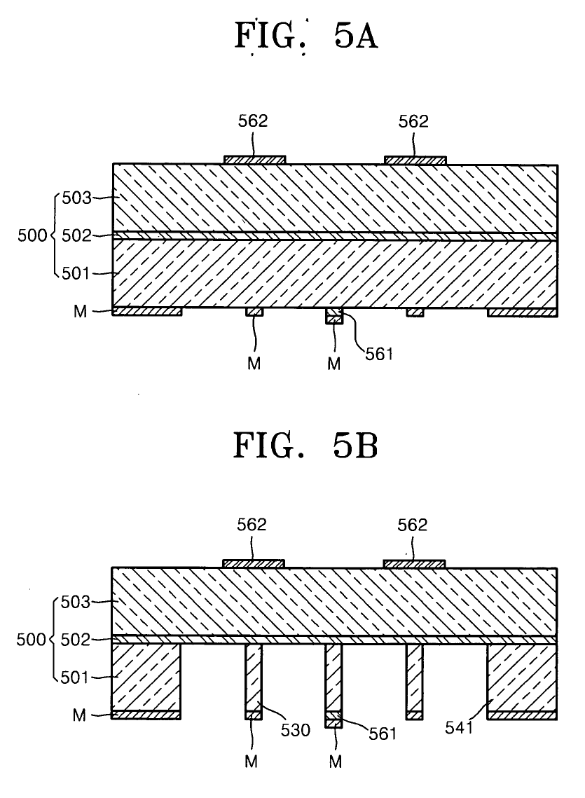

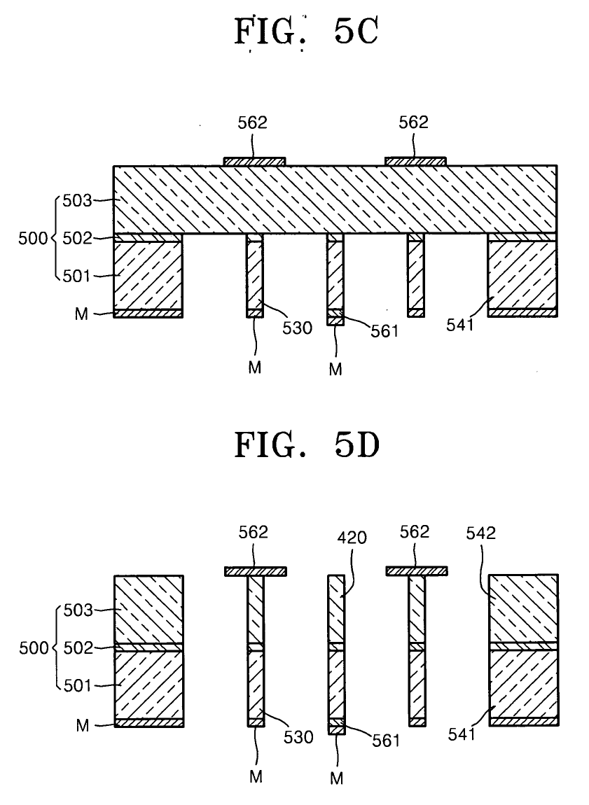

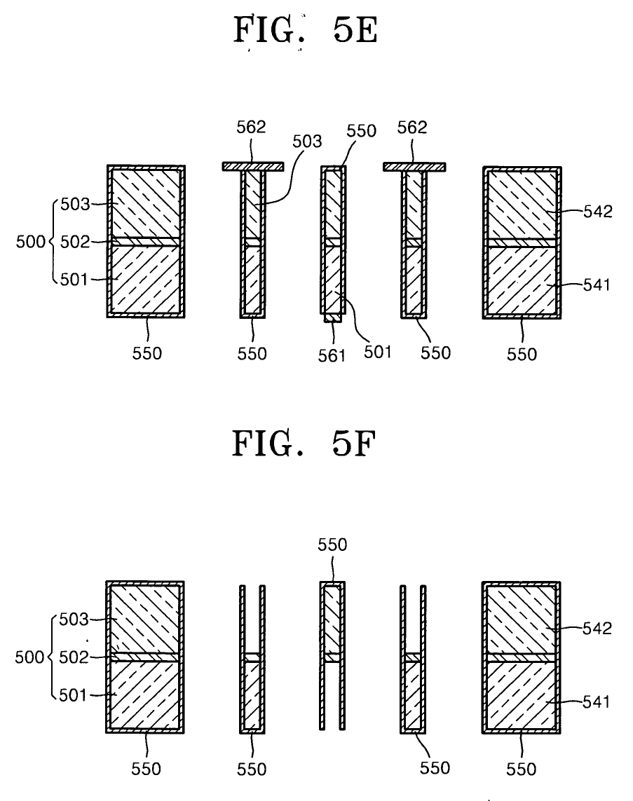

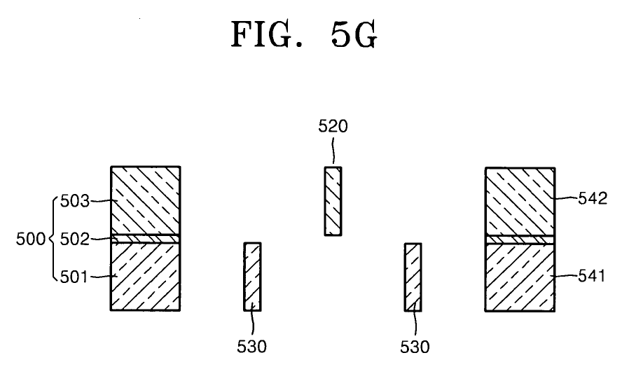

FIGS. 5A-5G are cross-sectional views illustrating steps in a method of forming comb electrodes using self alignment etching according to another exemplary embodiment of the present invention.

Referring to FIG. 5A, a SOI substrate 500 in which a first silicon layer 501, an insulating layer 502 and a second silicon layer 503 have been sequentially formed is prepared. The first and second silicon layers 501 and 503 may have a thickness of 500 μm, respectively. The insulating layer 502 may be a 2 μm thick silicon oxide layer.

Subsequently, an anti-oxidation layer 561 is formed on a portion of the first silicon layer 501 corresponding to a portion of the second silicon layer 503 in which a movable comb electrode will be formed. A mask M is formed on the anti-oxidation layer 561 and the portions of the first silicon layer 501 in which a stationary comb electrode and a frame will be formed. The mask M has different etch rates with respect to silicon and silicon oxide. The anti-oxidation layer 561 may be made of silicon nitride.

An anti-oxidation layer 562 is formed on a portion of the second silicon layer 503 corresponding to the portion of the first silicon layer 501 in which the stationary comb electrode will be formed. The anti-oxidation layer 562 may be made of silicon nitride. The anti-oxidation layer 562 may be formed using an alignment mark (not shown) formed in the first silicon layer 501 and may be wider than the portion of the first silicon layer 501 for forming the stationary comb electrode. The anti-oxidation layer 562 should not be in contact with the portion of the second silicon layer 503 for forming the movable comb electrode.

Referring to FIG. 5B, a portion the first silicon layer 501 exposed through the mask M is etched to expose the insulating layer 502 and to form stationary comb electrodes 530 and a portion 541 of a frame. Referring to FIG. 5C, the insulating layer 502 exposed through the mask M is etched. Referring to FIG. 5D, a portion of the second silicon layer 503 exposed through the mask M is etched to form the portion for forming the movable comb electrode and the remaining portion 542 of the frame. Referring to FIG. 5E, the mask M is removed. Subsequently, the exposed silicon layers are oxidized to form a silicon oxide layer 550 on the exposed structure.

Referring to FIG. 5F, the anti-oxidation layers 561 and 562 are removed, followed by removal of the underlying portions of the first and second silicon layers 501 and 503. Referring to FIG. 5G, the exposed silicon oxide layer 550 is removed to form movable and stationary comb electrodes 520 and 530.

According to the method of the exemplary embodiment for etching a Micro Electro-Mechanical Systems (MEMS) structure illustrated in FIGS. 5A-5G, the stationary and movable comb electrodes 520 and 530 are formed using the alignment mark formed in the first silicon layer 501, thereby eliminating an alignment error between upper and lower structures.

A method of forming comb electrodes using self alignment etching according to the exemplary embodiments of the present invention can reduce an alignment error in a MEMS structure consisting of upper and lower structures, thus allowing precise formation of a gap between comb electrodes.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming a stationary comb electrode and a movable comb electrode in first and second silicon layers of an SOI (Silicon-on-Insulator) substrate, respectively, the method comprising:
forming a first mask on a portion of the first silicon layer where the stationary comb electrode will be formed;
forming a second mask on the first mask and a portion of the first silicon layer corresponding to a portion of the second silicon layer where the movable comb electrode will be formed;
forming an anti-oxidation layer on a portion of the second silicon layer corresponding to the portion of the first silicon layer where the stationary comb electrode will be formed;
etching the first silicon layer exposed through the second mask to a predetermined depth;
removing the second mask and etching the first silicon layer exposed through the first mask so that a first portion of the first silicon layer corresponding to the portion of the second silicon layer for forming the movable comb electrode remains;
etching the insulating layer of the SOI substrate exposed through the first mask and the first portion;
etching the second silicon layer exposed through the first mask and the first portion;
removing the first mask and forming a silicon oxide layer on exposed portion of the first and second silicon layers;
removing the anti-oxidation layer and etching a portion of the second silicon layer not covered by the silicon oxide layer; and
removing the silicon oxide layer.

2. The method of claim 1, wherein the anti-oxidation layer is separated from the portion of the second silicon layer where the movable comb electrode will be formed.

3. The method of claim 1, wherein the anti-oxidation layer is wider than the portion of the first silicon layer where the stationary comb electrode will be formed.

4. The method of claim 1, wherein the anti-oxidation layer is made of silicon nitride.

5. The method of claim 1, wherein the anti-oxidation layer is formed using an alignment mark formed in the first silicon layer.

6. A method of forming a stationary comb electrode and a movable comb electrode in first and second silicon layers of an SOI (Silicon-on-Insulator) substrate respectively, the method comprising:
forming a first anti-oxidation layer on a portion of the first silicon layer corresponding to a portion of the second silicon layer where the movable comb electrode will be formed;
forming a second anti-oxidation layer on a portion of the second silicon layer corresponding to a portion of the first silicon layer where the stationary comb electrode will be formed;
forming a mask on the first anti-oxidation layer and the portion of the first silicon layer where the stationary comb electrode will be formed;
sequentially etching the first silicon layer, an insulating layer and the second silicon layer exposed through the mask;
removing the mask and forming a silicon oxide layer on exposed portions of the first and second silicon layers;
removing the first and second anti-oxidation layers and etching portions of the first and second silicon layers not covered by the silicon oxide layer; and
removing the silicon oxide layer.

7. The method of claim 6, wherein the second anti-oxidation layer is separated from the portion of the second silicon layer where the movable comb electrode will be formed.

8. The method of claim 6, wherein the second anti-oxidation layer is wider than the first anti-oxidation layer.

9. The method of claim 6, wherein the first and second anti-oxidation layers are made of silicon nitride.

10. The method of claim 6, wherein the second anti-oxidation layer is formed using an alignment mark formed in the first silicon layer.

11. A method of forming a stationary comb electrode and a movable comb electrode, the method comprising:
providing an SOI (Silicon-on Insulator) substrate comprising a first silicon layer, a second silicon layer and an insulator layer between the first and second silicon layers;
etching the first silicon layer from a first side of the SOI substrate;
etching the insulator layer from the first side of the SOI substrate;
etching the second silicon layer from the first side of the SOI substrate.

12. The method of claim 11, wherein the first silicon layer is etched to form the stationary comb electrode and the second insulator layer is etched to form the movable comb electrode.

13. The method of claim 11, further comprising forming first and second mask layers on the first silicon layer before etching the first silicon layer.

14. The method of claim 13, wherein the second mask layer is removed after the first silicon layer has been partially etched and before the etching of the first silicon layer is completed.

15. The method of claim 14, wherein the first silicon layer is etched to form the stationary comb electrode and the second insulator layer is etched to form the movable comb electrode;
wherein the first mask layer is formed at least on a portion of the first silicon layer corresponding to the stationary comb electrode; and
wherein the second mask layer is formed at least on a portion of the first silicon layer corresponding to the movable comb electrode.

16. The method of claim 15, wherein the first mask layer is not formed on the portion of the first silicon layer corresponding to the movable comb electrode.

17. The method of claim 11, further comprising forming a mask layers and an anti-oxidation layer on the first silicon layer before etching the first silicon layer.

18. The method of claim 17, wherein the first silicon layer is etched to form the stationary comb electrode and the second insulator layer is etched to form the movable comb electrode;
wherein the mask layer is formed at least on a portion of the first silicon layer corresponding to the stationary comb electrode; and
wherein the anti-oxidation layer is formed at least on a portion of the first silicon layer corresponding to the movable comb electrode.

19. The method of claim 18, wherein the anti-oxidation layer is not formed on the portion of the first silicon layer corresponding to the stationary comb electrode.
